(19) United States
(12) Patent Application Publication
(10) Pub. No.: US 2006/0046530 A1
(43) Pub. Date: Mar. 2, 2006

(54) LGA socket for CPU

(76) Inventor: Hsiang-Hua Wang, Taipei City (TW)

Correspondence Address: BIRCH STEWART KOLASCH & BIRCH, PO BOX 747, FALLS CHURCH, VA, 22040-0747, US

(21) Appl. No.: 11/014,981

(22) Filed: Dec. 20, 2004

(30) Foreign Application Priority Data
Aug. 27, 2004 (TW) 093125739

(51) Int. Cl. H05K 1/00

(52) U.S. Cl. 439/70

(57) ABSTRACT

Provided is an LGA socket of rectangle comprising four side walls wherein at least one of the walls is not fixed, a plastic housing provided on an enclosed space of the socket and comprising a plurality of apertures arranged in rows and columns, and a plurality of conductors each substantially concealed in the aperture and having a head being in contact with one of bottom contacts of a CPU in a vertical manner. Each unfixed wall comprises one or more latches on its inner surface such that pressing the CPU onto the space will cause the CPU to pass the latches until top of the CPU is fastened by the latches. The invention is advantageous for increasing contact reliability by causing no lateral displacement to heads of the conductors.

### FIELD OF THE INVENTION

The present invention relates to arrangements for mounting a CPU thereon and electrically coupling thereto and more particularly to an LGA type socket having substantially concealed conductors electrically coupled to a CPU mounted thereon.

### BACKGROUND OF THE INVENTION

A type of socket called Socket 775 for mounting Intel's P5 CPU thereon has been commercially available in early 2004. The CPU socket adopts latest LGA (Land Grid Array) technology and it is best illustrated in FIGS. 10 and 11. As shown, a metal mount is comprised of a socket 90 and a cover 95. The socket 90 is a rectangular frame. A plastic housing 93 is formed on an enclosed space of the socket 90 by heating. A plurality of apertures 930 arranged in rows and columns are provided in the housing 93 with only a rectangle formed by the apertures 930 being shown. Two stop members 901 and 902 are provided on opposite sides of the socket 90. A riser 91 is provided on a rear end of the socket 90. The riser 91 has a plurality of dents 910. A snapping member 92 bent upwardly, inward is provided on a front end of the socket 90. The rectangular cover 95 is slightly smaller than the socket 90 and comprises a central opening 951, two curved members 950 in its rear end, the curved members 950 inserted through the dents 910 and bent upwardly to form a hinge (i.e., the cover 95 and the socket 90 are hingedly coupled together), and a tab 952 projected from its front end. An L-shaped lever 96 comprises a bent section 960 projected from an intermediate recess of the snapping member 92 and has its hooked end adapted to snap onto a side of the socket 90 by pivoting.

As shown in FIG. 12, each of a plurality of LGA type conductors 94 comprises a horizontal soldering section 940 in its bottom, a bent base section 941 proximate the soldering section 940, an bent resilient section 942 in its top, and two opposite paws 943 projected from the base section 941. In installation, the base section 941 is inserted into the aperture 930 of the housing 93 with the paws 943 inserted into inner walls of the aperture 930 for fastening and the resilient section 942 extended obliquely beyond the aperture 930 to be in contact with contacts 610 of a CPU 61 when the CPU 61 is pressed thereon.

The CPU 61 is mounted on center of the socket 90 (i.e., on the conductors 94 in the housing 93) with the contacts 610 being in contact with the conductors 94. Next, push the cover 95 down to the end and then pivot the lever 96 downwardly until the tab 952 is engaged with and fastened by the bent section 960. As this position, the cover 95 is secured onto the CPU 61 by the lever 96.

However, the prior art suffered from several disadvantages. For example, the metal material of the mount including the socket, the cover, and the lever is relatively heavy. As such, one or more components of the mount may fall undesirably in the manufacturing process of attracting the mount by a magnetic member. Further, the socket, the cover, and the lever are assembled by interconnecting, snapping, pushing, and pressing operations, resulting in an increase of the manufacturing cost and a low yield. Furthermore, as shown in FIG. 12, the resilient section 942 obliquely projected from the aperture 930 is pressed and deformed by the CPU 61 mounted thereon. However, one or more resilient sections 942 may be excessively deformed or even damaged if one side of the CPU 61 is slanted or an excessive force is exerted in the pressing operation. As a result, a poor electrical contact of the conductors is occurred. Such design of exposing the resilient sections 942 from the housing 93 is disadvantageous. In addition, a virtual surface formed by tops of several hundred projected resilient sections 942 is not even due to allowance of mounting the conductors 94 in the apertures 930. Such uneven surface is called common surface degree and is required to be within a predetermined limit. However, a poor contact of the conductor 94 with the CPU 61 may occur if a distance between the top of the conductor 94 and the CPU 61 is larger than the predetermined limit. To the contrary, the top of the conductor 94 may be excessively deformed if the top of the conductor 94 projects too much. As an end, the whole socket is damaged. This is why such type of CPU socket has a low yield. Hence, a need for improvement exists.

### SUMMARY OF THE INVENTION

It is an object of the present invention to provide an LGA socket of rectangle comprising four side walls wherein at least one of the walls is not fixed; and a plastic housing provided on an enclosed space of the socket and comprising a plurality of apertures arranged in rows and columns; wherein each unfixed wall comprises one or more latches on its inner surface such that pressing a CPU onto the space will cause the CPU to pass the latches until a top of the CPU is fastened by the latches. By utilizing the present invention, the installation of CPU is easier and an electrical contact between the CPU and a plurality of conductors in the apertures is more secure.

It is another object of the present invention to provide a substantially concealed conductor having a top being in contact with a bottom of a CPU vertically so as to increase reliability of the contact, cause no lateral displacement to the conductor, and thus protect the conductor.

The above and other objects, features and advantages of the present invention will become apparent from the following detailed description taken with the accompanying drawings.

### BRIEF DESCRIPTION OF THE DRAWINGS

FIG. 1 is an exploded perspective view of a preferred embodiment of LGA socket for CPU according to the invention;

FIG. 2 is a top view of the socket with one hinged wall being pivoted away from its fastened position;

FIG. 3 is a sectional view depicting an arrangement of ends of the conductors projected from the housing and remaining portion thereof disposed in the apertures;

FIG. 4 is a sectional view depicting a CPU being about to mount onto the socket;

FIG. 5 is a view similar to FIG. 4 where the CPU has been mounted onto the socket;

FIG. 6 is a side view showing three different shapes of the conductor end (i.e., head);

FIG. 7 is top view showing a second embodiment of the socket with one detachable side being removed;

FIG. 8 is a perspective view showing one hinged side of the socket has been open so as to remove the CPU thereafter;

FIG. 9 is a perspective view showing a fourth embodiment of shape of the head;

FIG. 10 is a perspective view of a conventional LGA socket for CPU where the socket is in a closed position;

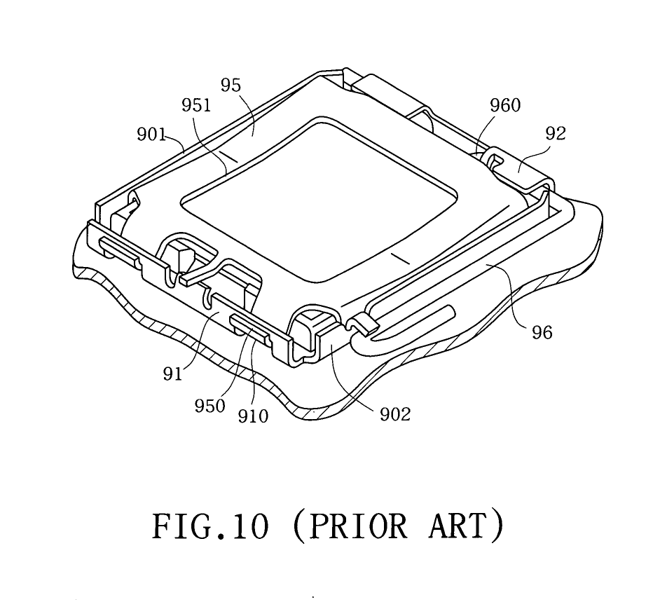

FIG. 11 is is a perspective view of the conventional LGA socket where the cover is open, the lever is lifted, and a CPU is about to mount on the housing; and

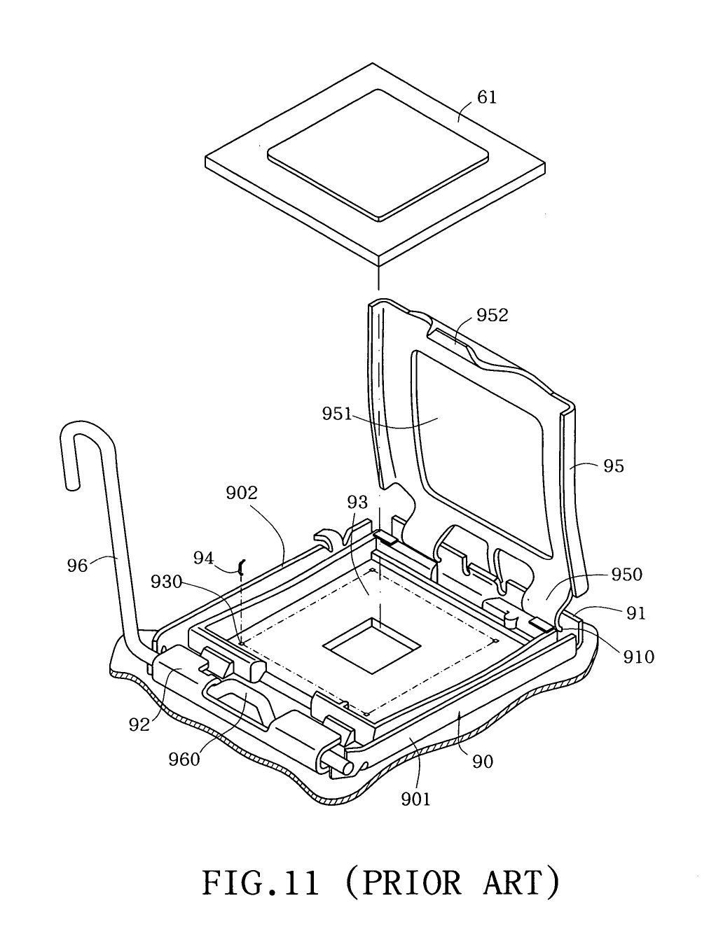

FIG. 12 is a sectional view depicting bottom contacts of the CPU to be in contact with the resilient sections of the conductors in installing the CPU on the housing.

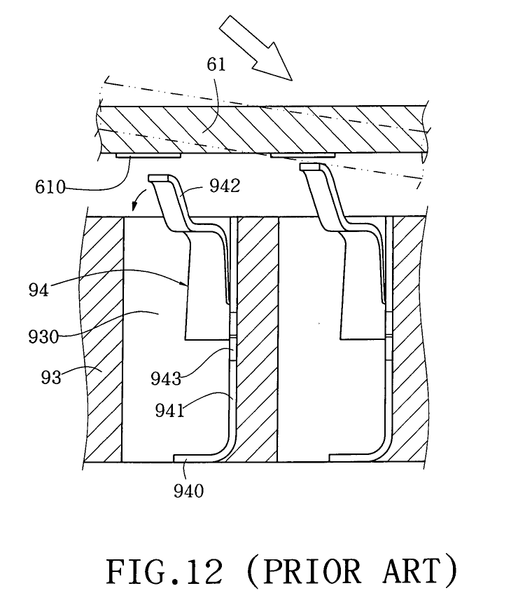

### DETAILED DESCRIPTION OF THE PREFERRED EMBODIMENTS

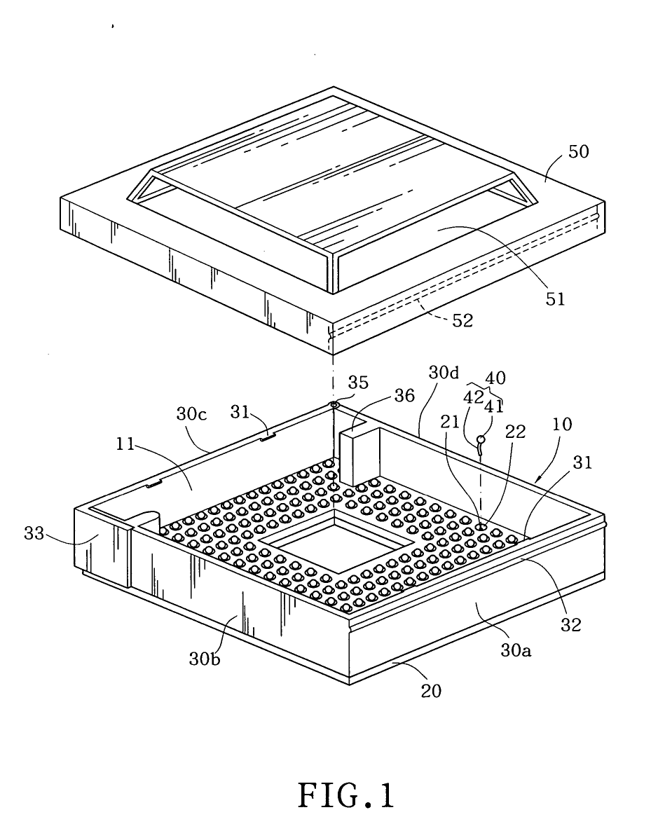

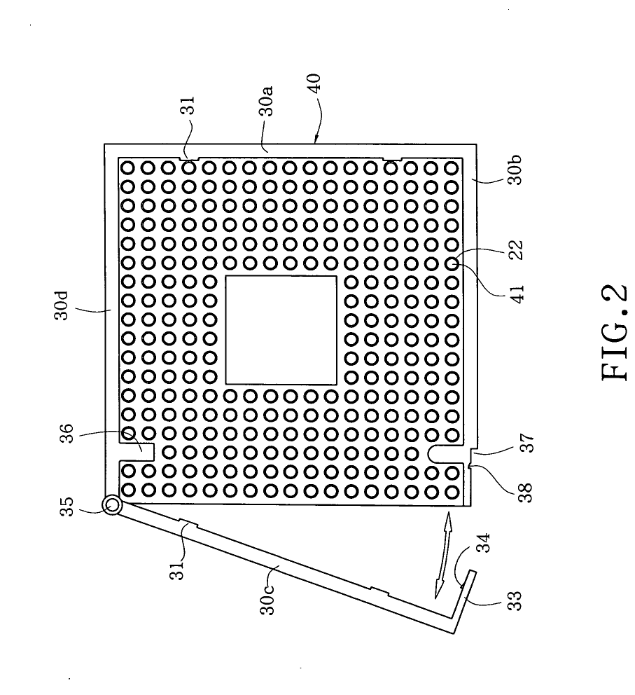

Referring to FIGS. 1, 2 and 8, there is shown an LGA type CPU socket 10 constructed in accordance with preferred embodiment of the invention. The socket 10 is made of lightweight material so as to reduce the manufacturing cost. The socket 10 is of rectangle and comprises four walls 30a, 30b, 30c, and 30d at four sides in which at least one of the walls (e.g., the wall 30c) is not fixed as detailed later. A plastic housing 20 is provided on an enclosed space 11 of the socket 10 and comprises a plurality of apertures 21 arranged in rows and columns and a central rectangular opening. The wall 30c is coupled to the wall 30d by a hinge 35. An L-shaped member 33 is formed at an open end of the wall 30c and is adapted to fasten an open end of the wall 30b as detailed later. In one configuration, a tab 34 is formed on an inner surface of the L-shaped member 33 and correspondingly a slot 38 is formed on a recessed portion 37 at the open end of the wall 30b. The thickness of the L-shaped member 33 is conformed to a distance between an outer surface of the recessed portion 37 and that of the wall 30b such that a flat outer surface is formed on the wall 30b (i.e., four side surfaces of the socket 10 are flat) and the tab 34 is inserted into the slot 38 after snapping the L-shaped member 33 onto the recessed portion 37. That is, both the walls 30c and 30b are fastened together. Each of the walls 30c and 30a further comprises two spaced latches 31 on its inner surface facing the space 11. Two projections 36 are extended inwardly into the space 11 from the walls 30d and 30b respectively.

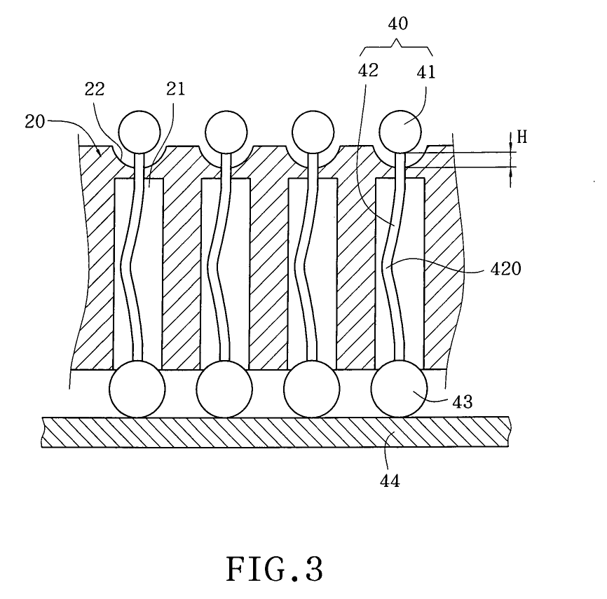

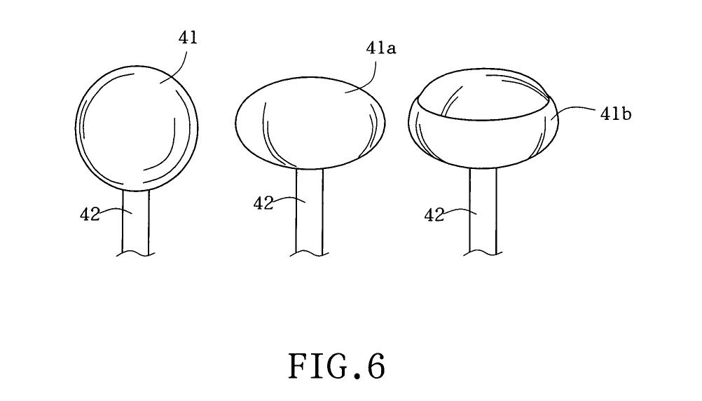

Referring to FIG. 3 in conjunction with FIG. 1, the aperture 21 is vertical and a half spherical dent 22 having a diameter larger than that of the aperture 21 is formed above the aperture 21. The conductor 40 comprises a spherical head 41 at its upper end, a tin ball 43 at its bottom end,, and a leg 42 coupled to both ends. The tin ball 43 is adapted to fasten onto a circuit board 44 in the embodiment. Alternatively, the tin ball 43 is eliminated and the conductor 40 is secured to the circuit board 44 directly by soldering in another embodiment. As shown in FIG. 6, the head 41 may be shaped as one shown in the middle (i.e., oval head 41a) or one shown in the right (i.e., irregular substantially oval head 41b). Further, the head 41, 41a, or 41b can be hollow for saving material or decreasing weight.

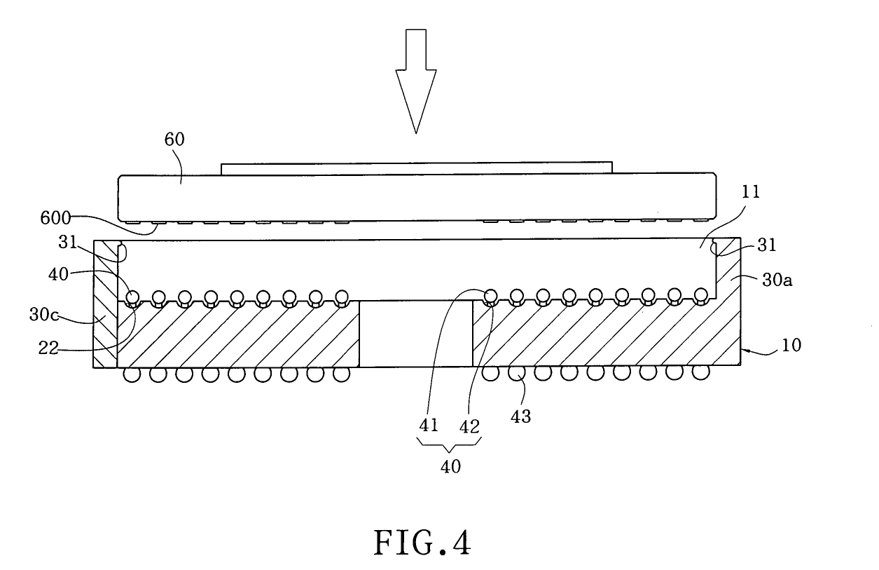

Referring to FIG. 3 again, the leg 42 comprises at least one bent section (one is shown) 420. The bent section 420 may be formed by inserting the leg 42 from a lower end of the aperture 21 through a closed end the aperture 21 and pressing the head 41 toward the aperture 21. The bent section 420 is resilient and is thus able to push the head 41 above a bottom of the dent 22 by a distance H. Referring to FIG. 4 in conjunction with FIG. 3, lower half portion of the head 41 may contact the dent 22 when the head 41 is pressed thereonto, i.e., the head 41 is confined in the dent 22 without being laterally displaced or dislodged. In brief, a distance between the bottom of the head 41 and the bottom of the dent 22 is limited to be no more than the small distance H.

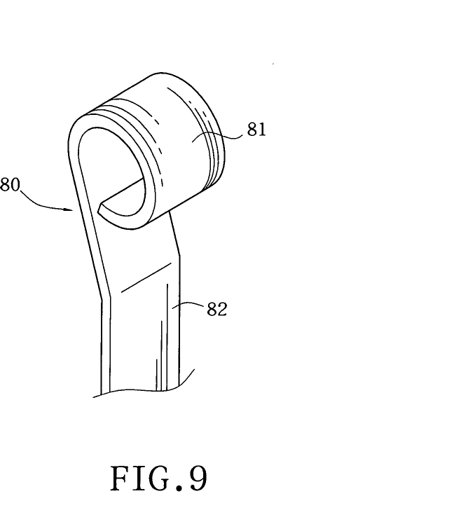

Referring to FIG. 9, there is shown another embodiment of the conductor 80. The conductor 80 is a flat metal member and comprises a curved head 81 and an elongate leg 82.

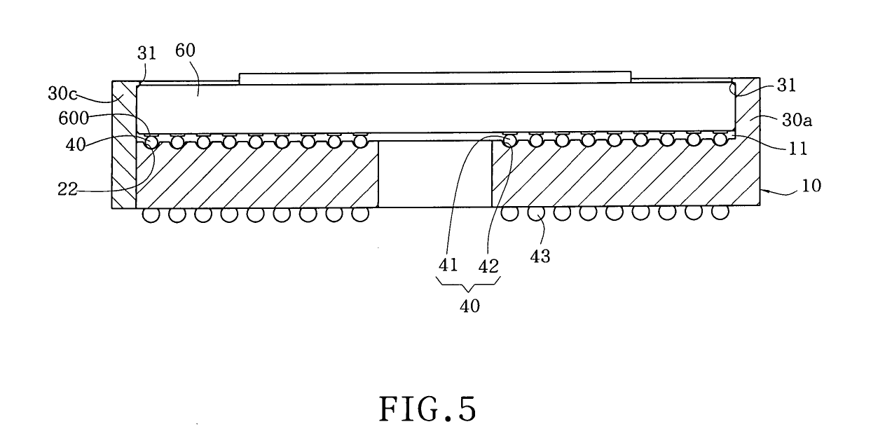

Referring to FIG. 5 in conjunction with FIG. 4, a CPU installation process will be described in detailed below. Press a CPU 60 onto the space 11 by passing the flexible latches 31 until the top of the CPU 60 is fastened by the latches 31. In this position, the heads 41 are pressed by contacts 600 on a bottom of the CPU 60 and a resilient force is thus stored in the bent section 420. As a result, an electrical connection between the CPU 60 and the conductors 40 is established. It is seen that the substantially concealed conductors 40 having its heads 41 being in contact with the bottom contacts 600 of the CPU 60 vertically. This has the benefits of increasing reliability of the contact, causing no lateral displacement to the conductors 40, and thus protect the conductors 40.

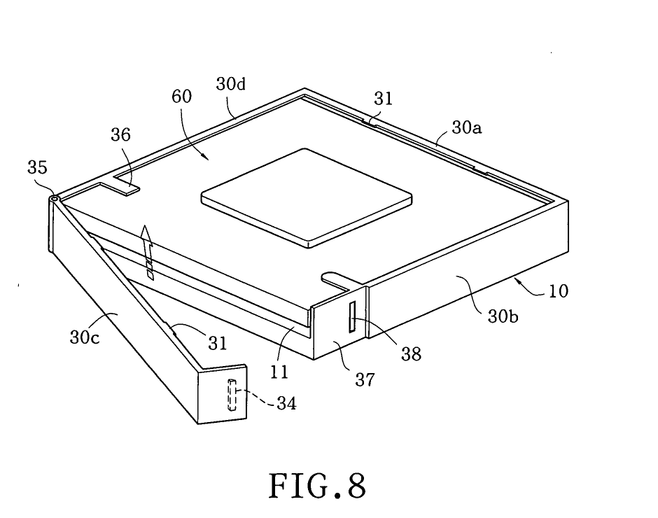

Referring to FIG. 8, for removing the CPU 60 a user may pivot the wall 30c outwardly to disengage the latches 31 of the wall 30c from the CPU 60. The unfastened CPU 60 then bounces up slightly particularly in its portion adjacent the wall 30c as indicated by arrow. The user is thus able to remove the CPU 60 from the socket 10.

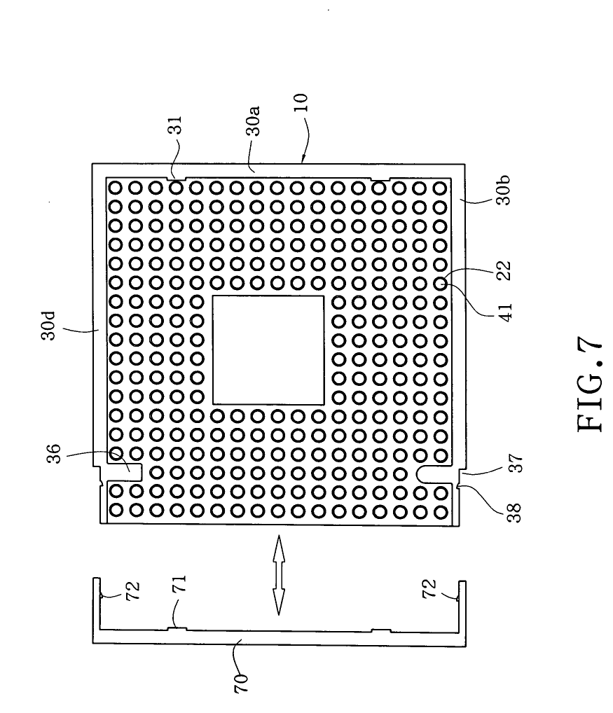

Referring to FIG. 7, there is shown a second embodiment of the socket with a detachable wall 70. The wall 70 has a U section and comprises two spaced latches 71 on its inner surface and two tabs 72 each formed on an inner surface of either L-shaped member at its open end. Correspondingly, a slot 38 is formed on a recessed portion 37 at the open end of each of the walls 30b and 30d. Similarly, the tabs 72 are adapted to insert into the slots 38 after snapping the L-shaped members of the wall 70 onto the recessed portions 37. That is, the walls 70, 30b, and 30c are fastened together. For detaching the wall 70, a user may pull the L-shaped members thereof prior to removing the whole wall 70 from the socket 10.

Referring to FIG. 1 again, there is further provided a rectangular cover 50 having four side flanges. The cover 50 is adapted to protect the conductors 40 and comprises four side openings 51 below a projected roof. The provision of the openings 51 is for ventilation in the soldering process and preventing dust from entering. The cover 50 further comprises four side ridges 52 being adapted to matingly engage with four troughs 32 formed on outer surfaces of the walls 30a, 30b, 30c, and 30d for securing the cover 50 onto the socket 10.

While the invention herein disclosed has been described by means of specific embodiments, numerous modifications and variations could be made thereto by those skilled in the art without departing from the scope and spirit of the invention set forth in the claims.

What is claimed is:

1. An LGA socket of rectangle comprising:
four walls at four sides wherein at least one of the walls is not fixed; and
a plastic housing provided on an enclosed space of the socket and comprising a plurality of apertures arranged in rows and columns;
wherein each unfixed wall comprises one or more latches on its inner surface such that pressing a CPU onto the space will cause the CPU to pass the latches until a top of the CPU is fastened by the latches.

2. The LGA socket of claim 1, wherein each unfixed wall comprises a hinge formed at one end coupled to an open end of the adjacent first wall and an L-shaped member formed at the other end being adapted to fasten an open end of the adjacent second wall.

3. The LGA socket of claim 2, wherein the L-shaped member comprises a tab formed on its inner surface, further comprising a slot formed on the open end of the adjacent second wall for tightly receiving the tab therein.

4. The LGA socket of claim 3, further comprising a recessed portion formed on an outer surface of the adjacent second wall and wherein a distance between an outer surface of the recessed portion and that of the adjacent second wall is conformed to a thickness of the L-shaped member.

5. The LGA socket of claim 1, further comprising a dent formed above each aperture.

6. The LGA socket of claim 5, wherein the dent is of half spherical.

7. The LGA socket of claim 1, wherein each unfixed wall is of U shape and comprises one or more latches on its inner surface, two L-shaped members at its open ends, and two tabs each formed on an inner surface of the L-shaped member, further comprising a slot formed on an open end of each of the adjacent first and second walls for tightly receiving the tab therein.

8. The LGA socket of claim 1, further comprising a rectangular cover comprising four side ridges, and wherein each wall comprises a trough on its outer surface matingly engaged with the ridges for securing the cover onto the walls.

9. A conductor mounted in an LGA type CPU socket comprising:
an enlarged upper end as head;
a bottom end as bottom; and
a leg coupled to both ends,
wherein the leg comprises at least one resilient bent section.

10. The conductor of claim 9, wherein each of the head and the bottom is of oval.

11. The conductor of claim 9, wherein the head is of sphere.

12. The conductor of claim 9, wherein the head is hollow.

13. The conductor of claim 9, wherein the head is curved.

14. The conductor of claim 9, wherein the head and the leg are formed of a flat metal material and the head is curved.

15. An LGA socket of rectangle comprising:
a plastic housing provided on an enclosed space of the socket and comprising a plurality of apertures arranged in rows and columns, and a plurality of dents each formed above the aperture and having a diameter larger than that of the aperture; and
a plurality of conductors each including a spherical upper end as head, a spherical bottom end as bottom, and a leg coupled to both ends and including at least one resilient bent section,
wherein responsive to inserting the leg into the aperture a distance is formed between a bottom of the head and a bottom of the dent by a stored resilient force of the bent section; and the head is adapted to move downwardly no more than the distance in response to pressing the head by one of a plurality of contacts on a bottom of a CPU.

16. The LGA socket of claim 15, wherein the dent is of half spherical.

17. The LGA socket of claim 15, wherein the bent section is formed by inserting the leg from a lower end of the aperture through a closed end the aperture and pressing the head toward the aperture.

18. The LGA socket of claim 15, further comprising forming a tin ball on the bottom of the conductor.
